(19) United States
(12) Patent Application Publication
(10) Pub. No.: US 2025/0102904 A1
(43) Pub. Date: Mar. 27, 2025

(54) MASK AND METHOD OF MANUFACTURING THE SAME

(71) Applicant: Samsung Display Co., LTD., Yongin-si (KR)

(72) Inventors: JINWOO LEE, Yongin-si (KR); JEONGKUK KIM, Yongin-si (KR); DUCKJUNG LEE, Yongin-si (KR); SUGWOO JUNG, Yongin-si (KR); SUNGWON CHO, Yongin-si (KR); JUNHO JO, Yongin-si (KR)

(73) Assignee: Samsung Display Co., LTD., Yongin-si (KR)

(21) Appl. No.: 18/888,542

(22) Filed: Sep. 18, 2024

(30) Foreign Application Priority Data
Sep. 22, 2023 (KR) 10-2023-0127167

(51) Int. Cl. G03F 1/80; G03F 7/40

(52) U.S. Cl. CPC G03F 1/80; G03F 7/40

(57) ABSTRACT

A mask includes a frame including an opening and a mask sheet disposed on the frame, including a first surface and a second surface opposite to the first surface, and including a plurality of holes that penetrate the first surface and the second surface. A width of each of the plurality of holes increases as being closer to the second surface from the first surface.

### CROSS-REFERENCE TO RELATED APPLICATION(S)

This application claims priority to and benefits of Korean Patent Application No. 10-2023-0127167 under 35 U.S.C. § 119, filed on Sep. 22, 2023, the entire contents of which are incorporated herein by reference.

### BACKGROUND

### 1. Technical Field

Embodiments relate to a mask and a method of manufacturing the mask. More particularly, the embodiments relate to the mask used in the deposition process and the method of manufacturing the mask.

### 2. Description of the Related Art

A display device is a device that displays images to provide visual information to users. The display device includes a liquid crystal display, a light-emitting diode display, an organic light-emitting diode display, a quantum dot display, or the like.

To manufacture the display device, components included in the display device (e.g., a light-emitting layer) may be formed in cells formed on a substrate. A mask may be used to form the components. Holes corresponding to the cells may be formed in the mask. In case that the mask is deformed during a manufacturing process of the display device, defects may occur in the display device, such as the components not being formed in the cells.

The organic light-emitting display device has a self-emission characteristic and does not require a separate light source, unlike a liquid crystal display device, so that the thickness and weight may be reduced. For example, the organic light-emitting diode display exhibits high quality characteristics such as low power consumption, high luminance, and high reaction speed.

### SUMMARY

Embodiments provide a mask capable of manufacturing a high-resolution display device.

Embodiments provide a method of manufacturing the mask.

A mask according to an embodiment may include a frame including an opening and a mask sheet disposed on the frame, including a first surface and a second surface opposite to the first surface, and including a plurality of holes that penetrate the first surface and the second surface, wherein a width of each of plurality of holes increase as being closer to the second surface from the first surface.

In an embodiment, an angle between an inclination surface of each of the plurality of holes and the second surface of the mask sheet may be less than about 70 degrees.

In an embodiment, the plurality of holes may include a first hole and second hole, and an angle between an inclination surface of the first hole and a surface parallel to the second surface may be substantially equal to an angle between an inclination surface of the second hole and the surface parallel to the second surface.

In an embodiment, the plurality of holes may further include a third hole disposed in an outer side of the mask sheet, and an angle between a surface of the third hole adjacent to the mask sheet and the surface parallel to the second surface may be a right angle.

In an embodiment, the plurality of holes may overlap the opening of the frame.

In an embodiment, a portion of the mask sheet disposed between two holes adjacent to each other among the plurality of holes may have an inverse tapered shape in a cross-sectional view.

In an embodiment, each of the frame and the mask sheet may include a silicon.

In an embodiment, each of the frame and the mask sheet may include a metal material.

In an embodiment, each of the frame and the mask sheet may include a multi-layer structure.

A method of manufacturing a mask may include forming a preliminary mask sheet on a preliminary frame, forming a mask sheet including a first surface and a second surface opposite to the first surface and including a plurality of preliminary holes that penetrate the first surface and second surface by removing a portion of the preliminary mask sheet, forming a frame including an opening by removing a portion of the preliminary frame, and forming a plurality of holes of the mask sheet each having a width increasing as being closer to the second surface from the first surface by irradiating a laser toward the second surface of the mask sheet and expanding the preliminary holes.

In an embodiment, an angle between an inclination surface of each of the plurality of holes and a surface parallel to the second surface of the mask sheet may be less than about 70 degrees.

In an embodiment, the forming of the plurality of holes may include forming a repair hole that penetrates the first surface and the second surface and having a width increasing as being closer to the second surface from the first surface by irradiating the laser on a portion of the mask sheet disposed between a first hole and a second hole among the plurality of holes.

In an embodiment, the forming of the plurality of holes may further include removing a portion of the mask sheet disposed in sides of the preliminary holes by irradiating the laser on each of the preliminary holes.

In an embodiment, a width of the laser may be wider than a width of each of the preliminary holes.

In an embodiment, the forming of the mask sheet may include forming a first photoresist on a first surface of the preliminary mask sheet and forming the preliminary holes by removing a portion of the preliminary mask sheet that does not overlap the first photoresist by a first etching process, and forming the frame may include forming a second photoresist on a rear surface of the preliminary frame and forming the opening of the frame by removing a portion of the preliminary frame that does not overlap the second photoresist by a second etching process.

In an embodiment, the method may further include flattening the first surface of the mask sheet before forming the second photoresist.

In an embodiment, a portion of the mask sheet disposed between two holes adjacent to each other among the plurality of holes may have an inverse tapered shape in a cross-sectional view.

In an embodiment, the plurality of holes of the mask sheet may overlap the opening of the frame.

In an embodiment, the plurality of holes of the mask sheet may include a first hole and a second hole, and an angle between an inclination surface of the first hole and a surface parallel to the second surface may be substantially equal to an angle between an inclination surface of the second hole and the surface parallel to the second surface.

In an embodiment, the plurality of holes of the mask sheet may further include a third hole disposed in an outer side of the mask sheet, and an angle between a surface of the third hole adjacent to the mask sheet and the surface parallel to the second surface may be a right angle.

In a mask according to embodiments, the mask may include a frame defining an opening and a mask sheet disposed on the frame and defining a plurality of holes. The plurality of holes of the mask sheet may have an inclination angle less than about 70 degrees from a first surface of the mask sheet to a second surface of the mask sheet, and each may increase in a width. Accordingly, during a deposition process that a deposition material is deposited on a substrate using the mask, a shadow effect in which the deposition material is not deposited at locations corresponding to the plurality of holes of the mask sheet may be reduced.

In a method of manufacturing the mask according to embodiments, through a single laser irradiation, a process that forms the plurality of holes of the mask sheet and a repair process that forms a repair hole may be performed simultaneously. Accordingly, process time and cost may be reduced.

For example, a width of the laser emitted from the laser device may be adjusted to be larger than a width of one among the plurality of holes of the mask sheet. Accordingly, since inclination surfaces are simultaneously formed on sides of the hole, the process time and cost may be further reduced.

### BRIEF DESCRIPTION OF THE DRAWINGS

Illustrative, non-limiting embodiments will be more clearly understood from the following detailed description in conjunction with the accompanying drawings.

FIG. 1 is a schematic perspective view illustrating a mask according to an embodiment.

FIG. 2 is an exploded schematic perspective view illustrating the mask in FIG. 1 disassembled.

FIG. 3 is a schematic cross-sectional view illustrating an example of the mask in FIG. 1 taken along line X-Y.

FIGS. 4, 5, 6, 7, 8, 9, 10, 11, 12, 13, 14, and 15 are schematic views illustrating an example of a method of manufacturing the mask in FIG. 1.

FIG. 16 is a schematic cross-sectional view illustrating another example of a method of manufacturing the mask.

FIG. 17 is a schematic cross-sectional view illustrating still another example of a method of manufacturing the mask.

FIG. 18 is a schematic cross-sectional view illustrating another example of the mask in FIG. 1 taken along line X-Y.

FIG. 19 is a schematic cross-sectional view illustrating still another example of the mask in FIG. 1 taken along line X-Y.

FIG. 20 is a schematic cross-sectional view illustrating still another example of the mask in FIG. 1 taken along line X-Y.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DRI, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, masks in accordance with embodiments will be described in more detail with reference to the accompanying drawings. The same reference numerals are used for the same components in the drawings, and redundant descriptions of the same components will be omitted.

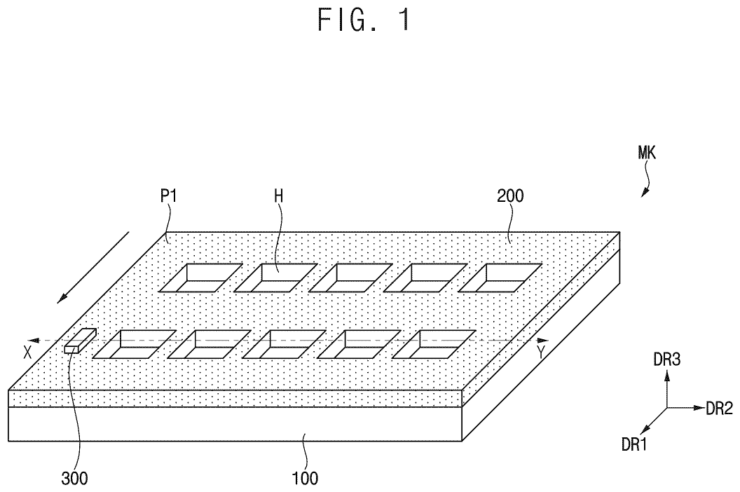

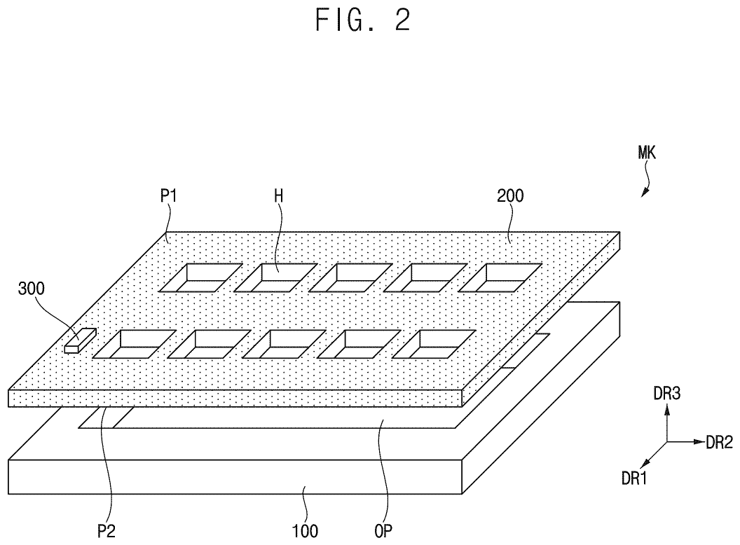

FIG. 1 is a schematic perspective view illustrating a mask according to an embodiment. FIG. 2 is an exploded schematic perspective view illustrating the mask in FIG. 1 disassembled.

In this specification, a plane may be defined by a first direction DR1 and a second direction DR2 that intersects the first direction DR1. For example, the first direction DR1 and the second direction DR2 may be perpendicular to each other. A third direction DR3 may be perpendicular to the plane.

Referring to FIGS. 1 and 2, a mask MK according to an embodiment may include a frame 100, a mask sheet 200, and an alignment key 300. The mask MK may be used in a deposition process to deposit a deposition material on a substrate (e.g., mother substrate). For example, the mask MK may be a device for depositing a light-emitting material (e.g., an organic light-emitting material) on cells formed on the substrate. The light-emitting material may be a material that forms a light-emitting layer that generates light in a display device.

The frame 100 may be disposed in parallel to the first direction DR1 and the second direction DR2. An opening OP may be defined in the frame 100. The opening OP may penetrate the frame 100 along the third direction DR3. In an embodiment, a shape of the opening OP may be a square shape in a plan view. However, embodiments are not limited thereto, and the shape of the opening OP may have various shapes in a plan view. In an embodiment, the frame may include a silicon wafer.

The mask sheet 200 may be disposed on the frame 100. For example, a first portion of the mask sheet 200 may contact the frame 100. For example, a second portion of the mask sheet 200 may overlap the opening OP. Accordingly, a portion of frame 100 that contacts the first portion of the mask sheet 200 may support the mask sheet 200. In an embodiment, the mask sheet 200 may include a inorganic material. The inorganic material may include a silicon (Si), a silicon nitride (SiNₓ), a silicon oxide (SiOₓ), a silicon oxynitride (SiNₓO_{y}), and the like. These may be used alone or in combination with each other.

The mask sheet 200 may include a first surface P1 and a second surface P2 facing each other. The second surface P2 of the mask sheet 200 may contact the frame 100. Holes H that penetrate the first surface P1 and the second surface P2 may be defined in the mask sheet 200. For example, the holes H may penetrate the first surface P1 and the second surface P2 along the third direction DR3. The holes H may be aligned along the first direction DR1 and the second direction DR2. For example, a shape of each of the holes H may have a square shape in a plan view. However, embodiments are not limited thereto, each of the holes H may have various shapes to from the light-emitting material.

In an embodiment, the holes H may overlap the opening OP. For example, all of the holes H may be disposed in the opening OP in a plan view. For example, a location of each of the holes H may correspond to a location that the deposition material is deposited on the substrate. For example, the deposition material may penetrate both the opening OP and the holes H, and may be deposited on the cells on the substrate.

The alignment key 300 may be disposed on the mask sheet 200. For example, the alignment key 300 may be disposed on the first surface P1 of the mask sheet 200. The alignment key 300 may align the mask MK to a specific location on the substrate. For example, the alignment key 300 may be dispose on the mask MK at a location corresponding to the cells on the substrate. For example, by contrasting a location that the deposition material is deposited on the cells and a location of holes H, the substrate and the mask MK may be aligned correctly. Accordingly, the alignment key 300 may have various patterns to align the mask MK. In an embodiment, the alignment key 300 may include a metal material.

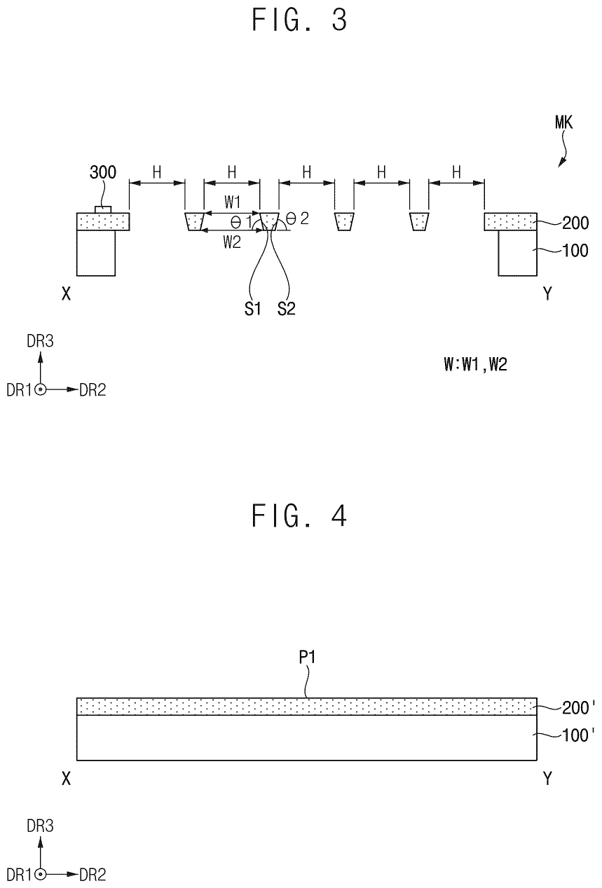

FIG. 3 is a schematic cross-sectional view illustrating an example of the mask in FIG. 1 taken along line X-Y.

Referring to FIGS. 2 and 3, a width (or diameter) W (e.g., W1 and W2) of each of the holes H in the second direction DR2 may increase as being closer to the second surface P2 from the first surface P1. For example, an upper width W1 of each of the holes H defined by the first surface P1 may be smaller than a lower width W2 of each of the holes H defined by the second surface P2. Accordingly, an inclination surface may be formed in the holes H. For example, a side surface of the mask sheet 200 exposed by a first hole among the holes H may include a first inclination surface S1. For example, a side surface of the first hole may include a first inclination surface S1. For example, a side surface of the mask sheet 200 exposed by a second hole and adjacent to the first hole in the second direction DR2 may include a second inclination surface S2. For example, a side surface of the second hole may include the second inclination surface S2.

The first inclination surface S1 and the second inclination surface S2 may be inclined in different directions. For example, a direction that the first inclination surface S1 is inclined may be a diagonal direction between the second direction DR2 and a direction opposite to the third direction DR3. For example, a direction that the second inclination surface S2 is inclined may be a diagonal direction between a direction opposite to the second direction DR2 and the direction opposite to the third direction DR3.

The first inclination surface S1 of the first hole may have a first inclination angle θ1. For example, the second inclination surface S2 of the second hole may have a second inclination angle θ2. For example, the first inclination angle θ1 may be an angle between the first inclination surface S1 and a surface parallel to the second surface P2. For example, the second inclination angle θ2 may be an angle between the second inclination surface S2 and the surface parallel to the second surface P2.

Since a width (or diameter) W of each of the holes H in the second direction DR2 may increase as being closer to the second surface P2 form the first surface P1, both the first inclination angle θ1 and the second inclination angle θ2 may be acute angles.

In an embodiment, an angle between an inclination surface of each of the holes H and the surface parallel to the second surface P2 may be less than about 70 degrees. For example, each of the first inclination angle θ1 and the second inclination angle θ2 may be less than about 70 degrees.

In an embodiment, the first inclination angle θ1 and the second inclination angle θ2 may substantially equal. For example, both the first inclination angle θ1 and the second inclination angle θ2 may be the same angle which is less than about 70 degrees.

In case that each of the first inclination angle θ1 and the second inclination angle θ2 is more than about 70 degrees, a shadow effect that the deposition material is not accurately deposited on the substrate at locations corresponding to the holes H may occur. Since a width (or diameter) W of each of the holes H in the second direction DR2, which is defined in the mask sheet 200 of the mask MK, increases as being closer to the second surface P2 from the first surface P1, and has an inclination angle less than about 70 degrees, the shadow effect may be decreased.

In an embodiment, a portion of the mask sheet 200 disposed between two holes adjacent to each other among the holes H may have an inverse tapered shape in a cross-sectional view. For example, since each of the holes H has the inclination surface, a portion of the mask sheet 200 disposed between the holes may have an inverse tapered shape in a cross-sectional view.

In an embodiment, an angle between a side surface of a hole where the hole disposed in an outer side of the mask sheet 200 among holes H is adjacent to the mask sheet 200 and the surface parallel to the second surface P2 may be a right angle. For example, an angle between the side surface of the hole which is disposed in the outer side of the mask sheet 200 among the holes H and is adjacent to an edge of the mask sheet 200 and the surface parallel to the second surface P2 may be the right angle.

FIGS. 4, 5, 6, 7, 8, 9, 10, 11, 12, 13, 14, and 15 are schematic views illustrating an example of a method of manufacturing the mask in FIG. 1.

Referring to FIG. 4, a preliminary mask sheet 200′ may be disposed on a preliminary frame 100′. In an embodiment, the preliminary frame 100′ may include a silicon. For example, the preliminary mask sheet 200′ may include a silicon.

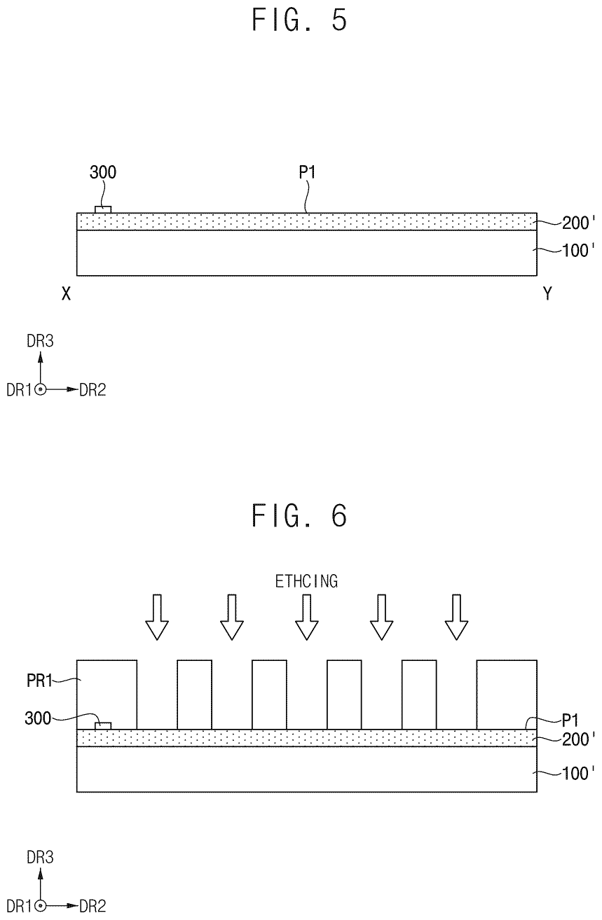

Referring to FIG. 5, the alignment key 300 may be disposed on the preliminary mask sheet 200′. For example, the alignment key 300 may be formed in an outer side of a first surface P1 of the preliminary mask sheet 200′ In an embodiment, the alignment key 300 may include a metal material.

Referring to FIG. 6, a first photoresist PR1 may be formed on the preliminary mask sheet 200′. For example, the first photoresist PR1 may cover the alignment key 300. For example, a photoresist layer may be formed on the first surface P1 of the preliminary mask sheet 200′, and the first photoresist PR1 may be formed by patterning the photoresist layer.

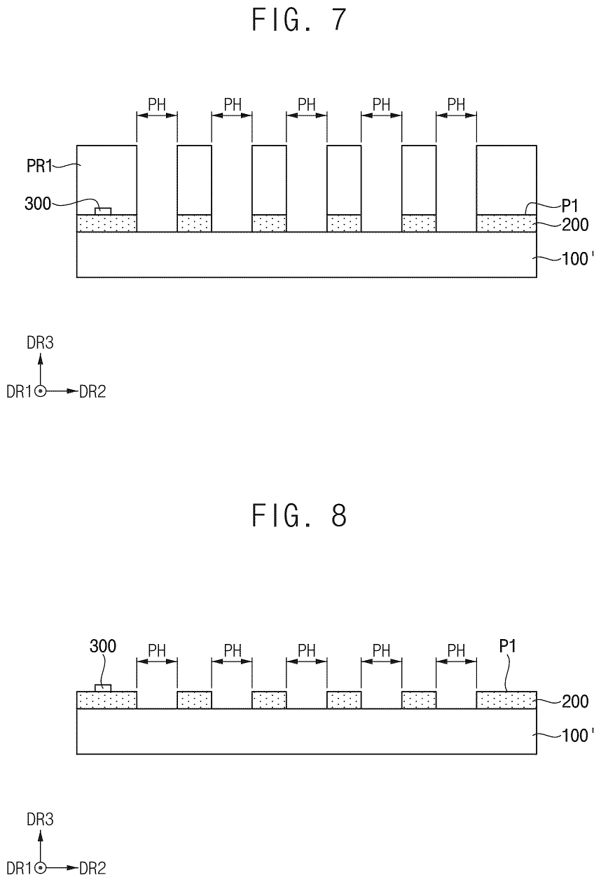

Openings may be formed in the first photoresist PR1 exposing the first surface P1 of the preliminary mask sheet 200′. The openings may correspond to (or overlap) preliminary holes (e.g., preliminary holes PH in FIG. 7) of the mask sheet (e.g., the mask sheet 200 in FIG. 7).

A first etching process may be performed after forming the first photoresist PR1. For example, the first etching process may be performed in a second surface P2 of the preliminary mask sheet 200′. For example, the preliminary mask sheet 200′ may be processed by the first etching process in the third direction DR3.

Referring to FIG. 7, a portion of the preliminary mask sheet 200′ may be removed by the first etching process. For example, a portion of the preliminary mask sheet 200′ which does not overlap the first photoresist PR1 may be removed. Accordingly, the preliminary holes PH that penetrate the first surface P1 and the second surface P2 of the preliminary mask sheet 200′ may be formed by the first etching process. For example, the first photoresist PR1 may be a positive photoresist.

However, embodiments are not limited thereto. For example, the first photoresist PR1 may be a negative photoresist. For example, the first photoresist PR1 may correspond to (or overlap) the preliminary holes PH. For example, the preliminary holes PH may be formed by removing a portion of the preliminary mask sheet 200′ that overlaps the first photoresist PR1 through the first etching process.

A portion of the preliminary mask sheet 200′ may not be removed by the first etching process. For example, the portion of the preliminary mask sheet 200′ that does not removed may be a preliminary repair hole (e.g., a preliminary repair hole PRH) that does not penetrate simultaneously the first surface P1 and the second surface P2. This will be explained later with reference to FIG. 14.

Referring to FIG. 8, after the first etching process, the mask sheet 200 defining the preliminary holes PH may be formed by removing a portion of preliminary mask sheet 200′. After forming the mask sheet 200, the first photoresist PR1 may be removed from the mask sheet 200. The preliminary holes PH may penetrate the mask sheet 200 in a thickness direction. For example, the preliminary holes PH may penetrate the first surface P1 and the second surface P2 in the third direction DR3. For example, a side surface of each of the preliminary holes PH may be perpendicular to the surface parallel to the second surface P2.

After the etching process, the first surface P1 of the mask sheet 200 may not be flat.

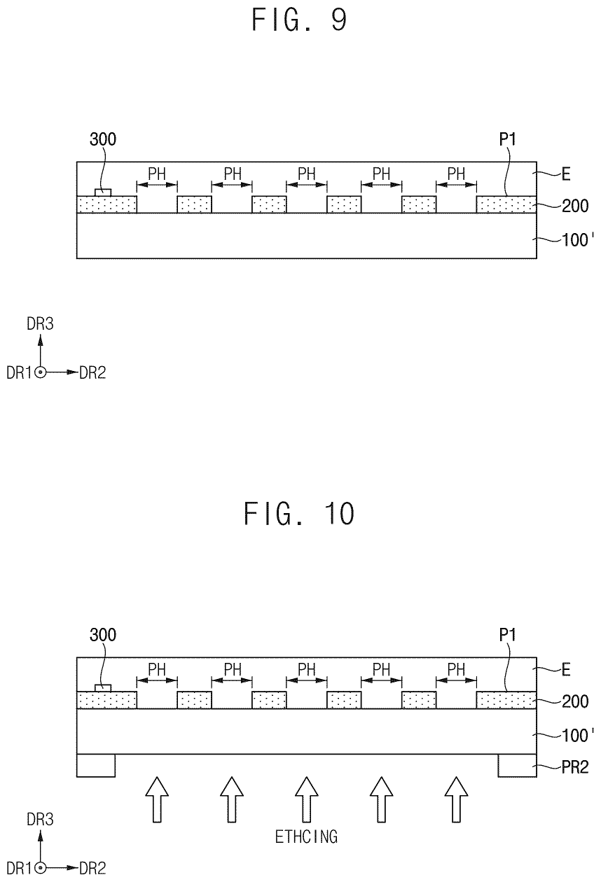

Referring to FIG. 9, a flattening process may be performed in the first surface P1 of the mask sheet 200. For example, a surface of the mask sheet 200 that does not be flat may be formed to be flat substantially through a flattening member E. The flattening member E may cover an upper surface of the mask sheet 200. For example, the flattening member E may include a photoresist.

Referring to FIG. 10, a second photoresist PR2 may be formed on a rear surface (or lower surface) of the preliminary frame 100′. For example, the second photoresist PR2 may cover a portion of the rear surface (or lower surface) of the preliminary frame 100′. For example, a photoresist layer may be formed on the rear surface (or lower surface) of the preliminary frame 100′, the second photoresist PR2 may be formed by patterning the photoresist layer.

A second etching process may be performed after forming the second photoresist PR2. For example, the second etching process may be performed in the rear surface (or lower surface) of the preliminary frame 100′. For example, the preliminary frame 100′ may be processed by the second etching process in the third direction DR3.

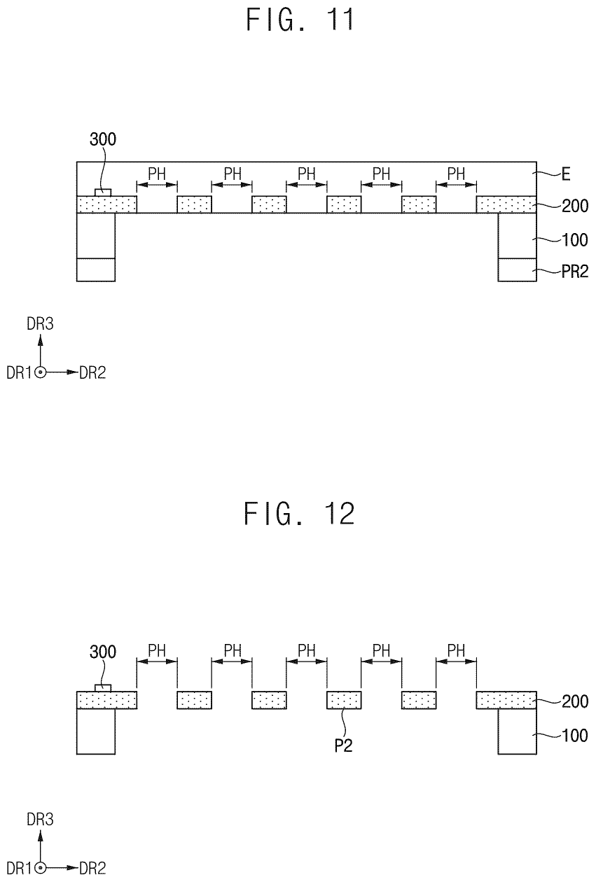

Referring to FIG. 11, a portion of the preliminary frame 100′ may be removed by the second etching process. For example, a portion of the preliminary frame 100′ that does not overlap the second photoresist PR2 may be removed. The opening OP that penetrates an upper surface and a rear surface (or lower surface) of the preliminary frame 100′ may be formed by the second etching process. For example, the second photoresist PR2 may be a positive photoresist.

However, embodiments are not limited thereto. For example, the second photoresist PR2 may be a negative photoresist. For example, a portion of the second photoresist PR2 that is formed on the preliminary frame 100′ may correspond to (or overlap) the opening OP. For example, a portion of the preliminary frame 100′ that overlap the second photoresist PR2 may be removed by the first etching process.

A width (or diameter) of the opening OP in the second direction DR2 may be wider than a width (or diameter) of each of the preliminary holes PH in the second direction DR2. In an embodiment, the preliminary holes PH may overlap the opening OP.

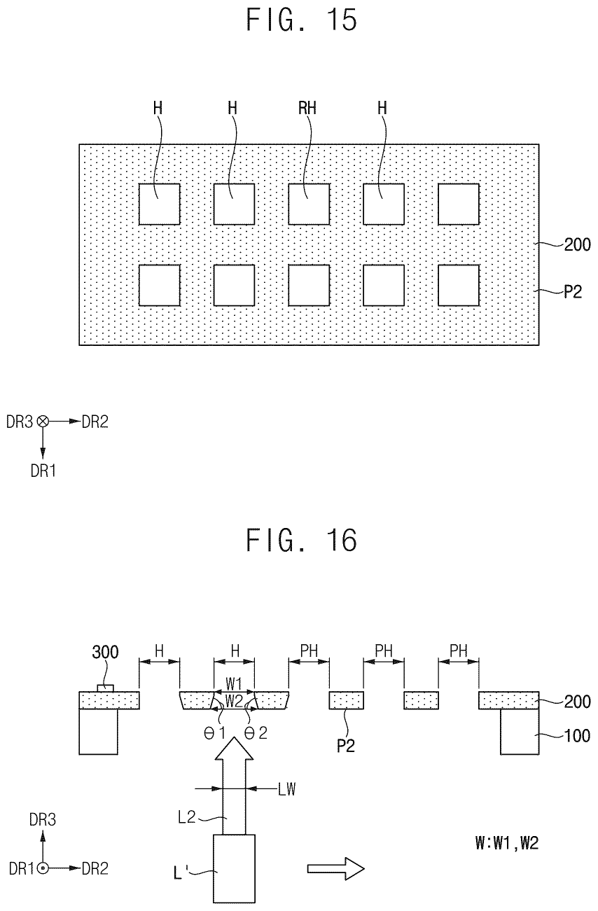

Referring to FIG. 12, the second photoresist PR2 may be removed from the frame 100. For example, the flattening member E may be removed from the mask sheet 200 and the alignment key 300. Accordingly, a structure combining the frame 100 defining the opening OP and the mask sheet 200 defining the preliminary holes PH may be formed. However, additional laser irradiation may be required to form the inclination surface of each of the preliminary holes PH and a repair hole (e.g., a repair hole RH in FIG. 15).

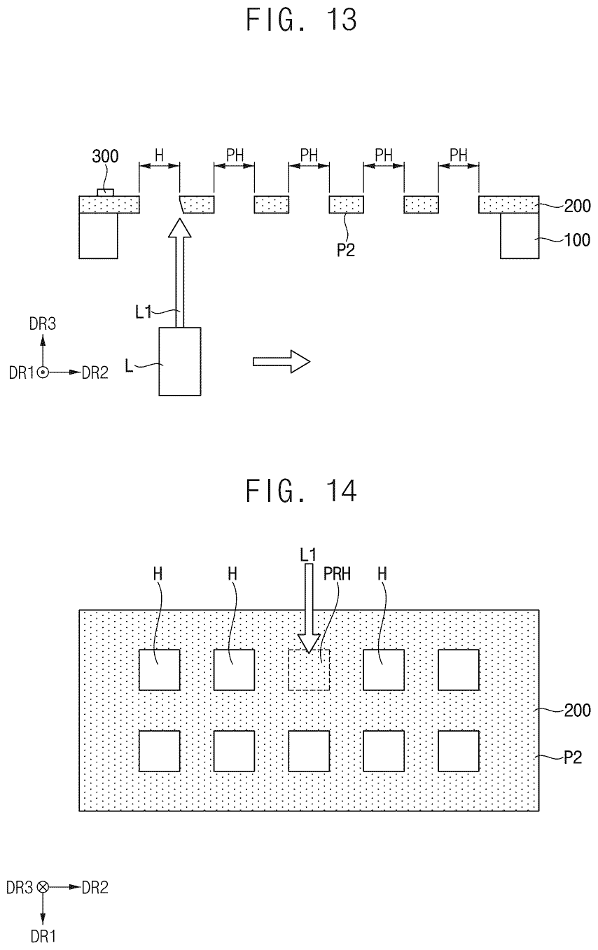

Referring to FIG. 13, a laser L1 may be irradiated toward the second surface P2 of the mask sheet 200 using a laser device L. A width (or diameter) of the preliminary holes PH may be expanded in the second direction DR2 through an irradiation of a laser L1 to form the holes H. For example, the laser L1 irradiated in the third direction DR3 may be irradiated on the second surface P2 of the mask sheet 200 adjacent to the preliminary holes PH, and a width (or diameter) of the preliminary holes PH in the second direction DR2 may be expanded.

For example, a portion of a side surface of the mask sheet 200 exposed by the preliminary holes PH may be removed by the irradiation of the laser L1, thereby the holes H having inclination surfaces may be formed.

For example, the laser L1 may be irradiated toward the second surface P2 of the mask sheet 200 disposed between the preliminary holes PH. For example, the laser L1 may be irradiated on a portion of the mask sheet 200 disposed between a first preliminary hole among the preliminary holes PH and a second preliminary hole adjacent to the first preliminary hole among the preliminary holes PH. Accordingly, after the irradiation of the laser L1 is processed, each of the first preliminary hole and the second preliminary hole may be expanded to form a first hole and a second hole each having an inclination surface.

In an embodiment, an acute angle between an inclination surface of the first hole, which is formed from the first preliminary hole, and the second surface P2 and an acute angle between an inclination surface of the second hole, which is formed from the second preliminary hole, and the second surface P2 may be substantially equal to each other.

The laser L1 may not be irradiated on an outer side of the mask sheet 200. Accordingly, an angle between a surface of a hole disposed the outer side of the mask sheet 200 among holes H adjacent to the mask sheet 200 and the surface parallel to the second surface P2 may be a right angle.

Referring to FIGS. 14 and 15, a preliminary repair hole PRH that does not penetrate the first surface P1 and the second surface P2 may be formed through the first surface P1. For example, the preliminary repair hole PRH may be disposed between two adjacent holes among the holes H formed by irradiating the laser L1 on the second surface P2. For example, a location of the preliminary repair hole PRH may be a location corresponding to (or overlapping) one hole among the holes H for depositing the organic light-emitting material.

In an embodiment, the preliminary repair hole PRH may also be disposed on the first surface P1. For example, the preliminary repair hole PRH may have a concave shape from the first surface P1. The preliminary repair hole PRH may have a concave shape from each of the first surface P1 and the second surface P2. In another embodiment, the preliminary repair hole PRH may penetrate the first surface P1 and the second surface P2. However, the preliminary repair hole PRH may not match the shape of the hole corresponding to (or overlapping) the cells on the substrate.

The laser L1 may be irradiated on the preliminary repair hole PRH. The laser L1 may be a laser emitted from the laser device L forming an inclination surface in FIG. 13. The laser L1 may be irradiated on the second surface P2 of the mask sheet 200 in the third direction DR3. The repair hole RH that simultaneously penetrates the first surface P1 and the second surface P2 may be formed from the preliminary repair hole PRH through the irradiation of the laser L1.

The repair hole RH may be one of the holes H in FIG. 1. The width (or diameter) of the repair hole RH in the second direction DR2 may increase as being closer to the second surface P2 from the first surface P1. In an embodiment, an angle formed between an inclination surface of the repair hole RH and the second direction DR2 may be less than about 70 degrees. In an embodiment, a shape of a portion of the mask sheet 200 disposed between the repair hole RH and a hole adjacent to the repair hole RH among the holes H may have an inverse tapered shape in a cross-sectional view.

As described above, a process of forming holes H each having an inclination surface and a repair process of forming a repair hole RH may be performed simultaneously by a single irradiation of the laser L1. Accordingly, process time and cost may be reduced.

FIG. 16 is a schematic cross-sectional view illustrating another example of a method of manufacturing the mask.

Hereinafter, descriptions that overlap those described with reference to FIGS. 4, 5, 6, 7, 8, 9, 10, 11, 12, 13, 14, and 15 will be omitted or simplified for descriptive convenience.

Referring to FIG. 16, a beam size of a laser device L′ may be adjusted to irradiate a laser L2 on the second surface P2. For example, a method of adjusting the beam size of the laser device L′ may include a method of adjusting a depth of focus of the laser device L′. Accordingly, a width (or diameter) LW of the laser L2 in the second direction DR2 may be adjusted. In an embodiment, in case that the focus of the laser device L′ is set to a point far away from the laser device L′ in the third direction DR3, the width (or diameter) LW of the laser L2 in the second direction DR2 may increase. In another embodiment, in case that the laser device L′ is focused on a point close to the laser device L′ in the third direction DR3, the width (or diameter) LW of the laser in the second direction DR2 may decrease.

As described above, the holes H may be formed by irradiating the laser L2 on the second surface P2 and expanding the preliminary holes PH. By adjusting the beam size of the laser device L′, the width (or diameter) LW of the laser L2 in the second direction DR2 may be larger than a width (or diameter) of each of the holes H on the first surface P1 in the second direction DR2.

Since the laser L2 is irradiated on the second surface P2, a width (or diameter) W (e.g., W1 and W2) of each of the holes H on the first surface P1 in the second direction DR2 may be substantially equal to a width (or diameter) of preliminary holes PH on the first surface P1 in the second direction DR2. For example, an upper width W1 of each of the holes H defined by the first surface P1 may be smaller than a lower width W2 of each of the holes H defined by the second surface P2. For example, since the width (or diameter) LW of the laser L2 in the second direction DR2 is wider than the width (or diameter) of preliminary holes PH in the second direction DR2, portions of mask sheet 200 disposed on sides (e.g., opposite sides) of a preliminary hole among the preliminary holes PH may be removed simultaneously. For example, by irradiating the laser L2 on the first preliminary hole, the first hole H1 having two inclination surfaces may be formed at once.

As described above, since the width (or diameter) LW of the laser L2 emitted from the laser device L′ in the second direction DR2 may increase by adjusting the depth of focus and a forming of the holes H may quickly be performed, process time and cost may be reduced.

FIG. 17 is a schematic cross-sectional view illustrating still another example of a method of manufacturing the mask.

Referring to FIG. 17, a width (or diameter) LW of a laser L3 in the second direction DR2 may be smaller than a width (or diameter) W of the holes H disposed on the first surface P1 in the second direction DR2. In order to form the first inclination angle θ1 and the second inclination angle θ2, the laser L3 may irradiate on sides (e.g., opposite sides) of a hole among the holes H in the second direction DR2 and a direction opposite to the second direction DR2 two times. Although a number of times the laser L3 is irradiated is larger than in the case in FIG. 16, a width (or diameter) of the repair hole (e.g., the repair hole RH in FIG. 15) in the second direction DR2 may be precisely adjusted.

In case that the width (or diameter) of the repair hole in the second direction DR2 is smaller than the width (or diameter) LW of the laser L3 of the laser device L″ in the second direction DR2 which is set arbitrarily, the width (or diameter) LW of the laser L3 may decrease. For example, the laser device L′ with arbitrarily set width (or diameter) may be focused in a direction opposite to the third direction DR3 from the mask sheet 200. Accordingly, the width (or diameter) LW of the laser L3 in the second direction DR2 may be adjusted to be equal to the width (or diameter) of the repair hole in the second direction DR2. The adjusted laser L3 may be irradiated on the preliminary repair hole (e.g., the preliminary repair hole PRH in FIG. 14), and the repair hole RH may be formed. The repair hole RH and each of the holes H may have the same width (or diameter) in the second direction DR2.

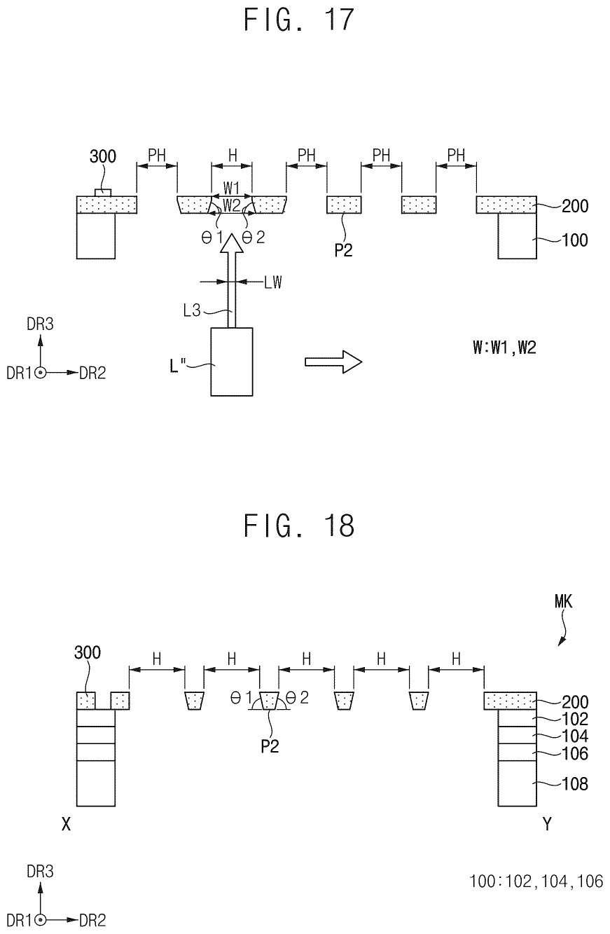

FIG. 18 is a schematic cross-sectional view illustrating another example of the mask in FIG. 1 taken along line X-Y.

The mask MK in FIG. 18 is substantially the equal to the mask MK in FIG. 3 except for a structure and shape of the frame 100 and the alignment key 300, respectively. Hereinafter, descriptions that overlap those described with reference to FIG. 3 will be omitted or simplified for descriptive convenience.

Referring to FIG. 18, in an embodiment, a frame 100 may include a multi-layer structure. The frame 100 may include a first layer 102, a second layer 104, a third layer 106, and a fourth layer 108. The first layer 102 may be disposed on the second layer 104. The second layer 104 may be disposed on the third layer 106. The third layer 106 may be disposed on the fourth layer 108.

In an embodiment, the frame 100 may include a metal material. The metal material may include a copper (Cu), a titanium (Ti), an aluminum (Al), and the like. These may be used alone in combination with each other. For example, the first layer 102 may include a copper, the second layer 104 may include a titanium, the third layer 106 may include an aluminum, and the fourth layer may include a silicon. However, embodiments are not limited thereto.

In an embodiment, the mask sheet 200 may include a metal material. For example, the metal material may include a nickel (Ni). For example, the mask sheet 200 may be formed by an electroforming method.

The alignment key 300 may be disposed on the frame 100. The alignment key 300 and the mask sheet 200 may include a same material. For example, the alignment key 300 and the mask sheet 200 may be formed as a same layer.

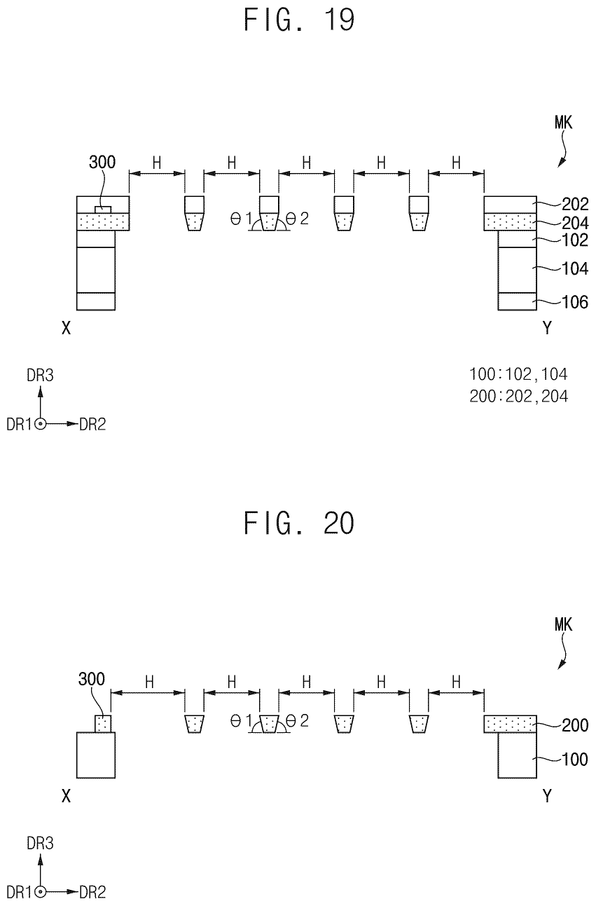

FIG. 19 is a schematic cross-sectional view illustrating still another example of the mask in FIG. 1 taken along line X-Y.

The mask MK in FIG. 19 is substantially the equal to the mask MK in FIG. 3 except for a structure and shape of the frame 100 and the mask sheet 200, respectively. Hereinafter, descriptions that overlap those described with reference to FIG. 3 will be omitted or simplified for descriptive convenience.

Referring to FIG. 19, a frame 100 may include a first layer 102, a second layer 104, and a third layer 106. In an embodiment, the frame 100 may include an inorganic material. The inorganic material may include a silicon, a silicon oxide, a silicon nitride, a silicon oxynitride, and the like. These may be used alone or in combination with each other. For example, the first layer 102 may include a silicon oxide, the second layer 104 may include a silicon, and the third layer 106 may include a silicon oxynitride. However, embodiments are not limited thereto.

The mask sheet 200 may include a first layer 202 and a second layer 204. In an embodiment, the mask sheet 200 may include an inorganic material. The inorganic material may include a silicon, a silicon oxide, a silicon nitride, a silicon oxynitride, and the like. These may be used alone or in combination with each other. For example, the first layer 202 may include a silicon nitride and the second layer 104 may include a silicon. However, embodiments are limited thereto.

FIG. 20 is a schematic cross-sectional view illustrating still another example of the mask in FIG. 1 taken along line X-Y.

The mask MK in FIG. 20 is substantially the equal to the mask MK in FIG. 18 except for a structure and shape of the mask sheet 200, respectively. Hereinafter, descriptions that overlap those described with reference to FIG. 3 will be omitted or simplified for descriptive convenience.

Referring to FIG. 20, the alignment key 300 and the mask sheet 200 may be formed as the same layer. For example, the alignment key 300 and the mask sheet 200 may include a same material. In an embodiment, the mask sheet 200 may include an invar. For example, the mask sheet 200 may be formed by an electroforming method.

The mask MK and the method of manufacturing the mask MK according to the embodiments may be applied to manufacture a display device included in a computer, a notebook, a mobile phone, a smartphone, a smart pad, a PMP, a PDA, an MP3 player, or the like.

Although the mask and the method of manufacturing the mask according to the embodiments have been described with reference to the drawings, the illustrated embodiments are examples, and may be modified and changed by a person having ordinary knowledge in the relevant technical field without departing from the technical spirit described in the following claims.

What is claimed is:

1. A mask comprising:
a frame including an opening; and
a mask sheet disposed on the frame, including a first surface and a second surface opposite to the first surface, and including a plurality of holes that penetrate the first surface and the second surface,
wherein a width of each of the plurality of holes increases as being closer to the second surface from the first surface.

2. The mask of claim 1, wherein an angle between an inclination surface of each of the plurality of holes and the second surface of the mask sheet is less than about 70 degrees.

3. The mask of claim 1, wherein
the plurality of holes include a first hole and second hole, and
an angle between an inclination surface of the first hole and a surface parallel to the second surface is substantially equal to an angle between an inclination surface of the second hole and the surface parallel to the second surface.

4. The mask of claim 3, wherein the plurality of holes further include a third hole disposed in an outer side of the mask sheet, and
an angle between a surface of the third hole adjacent to the mask sheet and the surface parallel to the second surface is a right angle.

5. The mask of claim 1, wherein the plurality of holes overlap the opening of the frame.

6. The mask of claim 1, wherein a portion of the mask sheet disposed between two holes adjacent to each other among the plurality of holes has an inverse tapered shape in a cross-sectional view.

7. The mask of claim 1, wherein each of the frame and the mask sheet includes a silicon.

8. The mask of claim 1, wherein each of the frame and the mask sheet includes a metal material.

9. The mask of claim 1, wherein each of the frame and the mask sheet includes a multi-layer structure.

10. A method of manufacturing a mask, the method comprising:
forming a preliminary mask sheet on a preliminary frame;
forming a mask sheet including a first surface and a second surface opposite to the first surface and including a plurality of preliminary holes that penetrate the first surface and second surface by removing a portion of the preliminary mask sheet;
forming a frame including an opening by removing a portion of the preliminary frame; and
forming a plurality of holes of the mask sheet, each hole having a width increasing as being closer to the second surface from the first surface by irradiating a laser toward the second surface of the mask sheet and expanding the preliminary holes.

11. The method of claim 10, wherein an angle between an inclination surface of each of the plurality of holes and a surface parallel to the second surface of the mask sheet is less than about 70 degrees.

12. The method of claim 10, wherein the forming of the plurality of holes includes forming a repair hole that penetrates the first surface and the second surface and having a width increasing as being closer to the second surface from the first surface by irradiating the laser on a portion of the mask sheet disposed between a first hole and a second hole among the plurality of holes.

13. The method of claim 12, wherein the forming of the plurality of holes further includes removing a portion of the mask sheet disposed in sides of the preliminary holes by irradiating the laser on each of the preliminary holes.

14. The method of claim 12, wherein a width of the laser is wider than a width of each of the preliminary holes.

15. The method of claim 10, wherein the forming of the mask sheet includes:
forming a first photoresist on a first surface of the preliminary mask sheet; and
forming the preliminary holes by removing a portion of the preliminary mask sheet that does not overlap the first photoresist by a first etching process, and the forming of the frame includes:
forming a second photoresist on a rear surface of the preliminary frame; and
forming the opening of the frame by removing a portion of the preliminary frame that does not overlap the second photoresist by a second etching process.

16. The method of claim 15, the method further comprising:
flattening the first surface of the mask sheet before forming the second photoresist.

17. The method of claim 10, wherein a portion of the mask sheet disposed between two holes adjacent to each other among the plurality of holes has an inverse tapered shape in a cross-sectional view.

18. The method of claim 10, wherein the plurality of holes overlap the opening of the frame.

19. The method of claim 10, wherein
the plurality of holes of the mask sheet include a first hole and a second hole, and
an angle between an inclination surface of the first hole and a surface parallel to the second surface is substantially equal to an angle between an inclination surface of the second hole and the surface parallel to the second surface.

20. The method of claim 19, wherein
the plurality of holes of the mask sheet further include a third hole disposed in an outer side of the mask sheet, and
an angle between a surface of the third hole adjacent to the mask sheet and the surface parallel to the second surface is a right angle.
